(19) United States
(12) Patent Application Publication
(10) Pub. No.: US 2026/0215061 A1
(43) Pub. Date: Jul. 23, 2026

(54) DISPLAY PANEL AND ELECTRONIC DEVICE INCLUDING THE SAME

(71) Applicant: Samsung Display Co., Ltd., Yongin-si (KR)

(72) Inventor: Yukhyun Nam, Yongin-si (KR)

(21) Appl. No.: 19/410,862

(22) Filed: Dec. 5, 2025

(30) Foreign Application Priority Data
Jan. 17, 2025 (KR) 10-2025-0007546

(51) Int. Cl. H10H 29/855; H10H 29/01; H10H 29/37

(52) U.S. Cl. CPC H10H 29/8552; H10H 29/012; H10H 29/0363; H10H 29/37

(57) ABSTRACT

A display panel includes: a plurality of light-emitting diodes each including a pixel electrode, an intermediate layer, and an opposite electrode; a first light-shielding layer on the plurality of light-emitting diodes and including a plurality of first openings respectively overlapping the plurality of light-emitting diodes; and a second light-shielding layer on the first light-shielding layer and including a plurality of second openings respectively overlapping the plurality of first openings, wherein a first width of the first light-shielding layer between two adjacent first openings of the plurality of first openings is greater than a second width of the second light-shielding layer between two adjacent second openings of the plurality of second openings, and the second light-shielding layer includes a liquid-repellent material.

### CROSS-REFERENCE TO RELATED APPLICATION

The present application claims priority to and the benefit of Korean Patent Application No. 10-2025-0007546, filed on January 17, 2025, in the Korean Intellectual Property Office, the entire disclosure of which is incorporated herein by reference.

### BACKGROUND

### Field

Aspects of some embodiments relate to a display panel including a light-emitting diode. Aspects of some embodiments relate to an electronic device including the display panel.

### Description of the Related Art

Electronic devices may display images or videos by using display panels provided therein. Display panels may visually display data. Display panels may provide images or videos by using light-emitting diodes. The use of display panels has become more diverse, and various designs have been attempted to improve the quality of display panels.

The above information disclosed in this Background section is only for enhancement of understanding of the background and therefore the information discussed in this Background section does not necessarily constitute prior art.

### SUMMARY

An optical functional layer may be provided in a display panel to relatively improve the quality of the display panel. The optical functional layer may include at least a light-shielding layer and a color filter. The color filter may transmit light of a wavelength band corresponding to light emitted from a light-emitting diode of the display panel, thereby relatively improving display quality. The light-shielding layer may relatively reduce the deterioration of display quality caused by external light entering the display panel, being reflected within the display panel, and being perceived by the user. One or more embodiments include a light-shielding layer having a structure capable of relatively improving the quality of a display panel. However, one or more embodiments are not limited to this objective.

Additional aspects will be set forth in part in the description which follows and, in part, will be apparent from the description, or may be learned by practice of the presented embodiments of the disclosure.

According to one or more embodiments, a display panel includes a plurality of light-emitting diodes each including a pixel electrode, an intermediate layer, and an opposite electrode, a first light-shielding layer arranged on the plurality of light-emitting diodes and including a plurality of first openings respectively overlapping the plurality of light-emitting diodes, and a second light-shielding layer arranged on the first light-shielding layer and including a plurality of second openings respectively overlapping the plurality of first openings, wherein a first width of the first light-shielding layer arranged between two adjacent first openings of the plurality of first openings is greater than a second width of the second light-shielding layer arranged between two adjacent second openings of the plurality of second openings, and the second light-shielding layer includes a liquid-repellent material.

According to some embodiments, the first light-shielding layer may include a liquid-repellent material.

According to some embodiments, a thickness of the first light-shielding layer may be 2 (or about 2) micrometers or less.

According to some embodiments, a thickness of the second light-shielding layer may be 5 (or about 5) micrometers or less.

According to some embodiments, the first light-shielding layer may include a first upper surface, a first lower surface, and a first side surface extending between the first upper surface and the first lower surface, the second light-shielding layer may include a second upper surface, a second lower surface, and a second side surface extending between the second upper surface and the second lower surface, and the first upper surface and the second lower surface may be in direct contact with each other.

According to some embodiments, an angle between the first lower surface and the first side surface may be 55° (or about 55°) or less.

According to some embodiments, an angle between the second lower surface and the second side surface may be 90° (or about 90°) or less.

According to some embodiments, in a direction parallel to the first lower surface, a distance between an edge of the first lower surface and an edge of the second upper surface may be 4.5 (or about 4.5) micrometers or less.

According to some embodiments, the display panel may further include a pixel-defining layer arranged under the first light-shielding layer and covering an edge area of the pixel electrode, wherein a straight line connecting an edge of the pixel-defining layer in contact with the pixel electrode and an edge of the first lower surface of the first light-shielding layer forms an angle of 55° (or about 55°) to 65° (or about 65°) with an upper surface of the pixel electrode.

According to some embodiments, in a direction parallel to the first lower surface, a distance between the edge of the pixel-defining layer in contact with the pixel electrode and the edge of the first lower surface of the first light-shielding layer may be 4 (or about 4) micrometers to 6 (or about 6) micrometers.

According to one or more embodiments, a display panel includes a plurality of light-emitting diodes each including a pixel electrode, an intermediate layer, and an opposite electrode, a pixel-defining layer including an opening overlapping the pixel electrodes of the plurality of light-emitting diodes and covering an edge area of the pixel electrode, a first light-shielding layer arranged on the pixel-defining layer and overlapping the pixel-defining layer, the first light-shielding layer including a first upper surface, a first lower surface, and a first side surface connecting the first upper surface and the first lower surface to each other, and a second light-shielding layer arranged on the first light-shielding layer and overlapping the first light-shielding layer, the second light-shielding layer including a second upper surface, a second lower surface, and a second side surface connecting the second upper surface and the second lower surface to each other, wherein an angle formed by a straight line connecting an edge of the pixel-defining layer in contact with an upper surface of the pixel electrode and an edge of the first lower surface with the upper surface of the pixel electrode, or an angle formed by a straight line connecting the edge of the pixel-defining layer in contact with the upper surface of the pixel electrode and an edge of the second upper surface is 55° (or about 55°) to 65° (or about 65°).

According to some embodiments, the second light-shielding layer may include a liquid-repellent material.

According to some embodiments, a width of the first upper surface of the first light-shielding layer may be greater than a width of the second lower surface of the second light-shielding layer.

According to some embodiments, a distance between the first upper surface and the first lower surface may be 2 (or about 2) micrometers or less.

According to some embodiments, a distance between the second upper surface and the second lower surface may be 5 (or about 5) micrometers or less.

According to some embodiments, an angle between the first lower surface and the first side surface may be 55° (or about 55°) or less.

According to some embodiments, an angle between the second lower surface and the second side surface may be 90° (or about 90°) or less.

According to some embodiments, in a direction parallel to the first lower surface, a distance between the edge of the first lower surface and the edge of the second upper surface may be 4.5 (or about 4.5) micrometers or less.

According to some embodiments, in a direction parallel to the first lower surface, a distance between the edge of the pixel-defining layer in contact with the upper surface of the pixel electrode and the edge of the first lower surface of the first light-blocking layer may be 4 (or about 4) micrometers to 6 (or about 6) micrometers.

According to one or more embodiments, an electronic device includes a display panel, wherein the display panel includes a plurality of light-emitting diodes each including a pixel electrode, an intermediate layer, and an opposite electrode, a first light-shielding layer arranged on the plurality of light-emitting diodes and including a plurality of first openings respectively overlapping the plurality of light-emitting diodes, and a second light-shielding layer arranged on the first light-shielding layer and including a plurality of second openings respectively overlapping the plurality of first openings, wherein a first width of the first light-shielding layer arranged between two adjacent first openings from among the plurality of first openings is greater than a second width of the second light-shielding layer arranged between two adjacent second openings from among the plurality of second openings, and the second light-shielding layer includes a liquid-repellent material.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a block diagram of an electronic device according to some embodiments;

FIGS. 2, 3, and 4 are schematic diagrams of an electronic device according to some embodiments;

FIG. 5 is a schematic plan view of an electronic device according to some embodiments;

FIG. 6 is an equivalent circuit diagram of a pixel of a display panel according to some embodiments;

FIG. 7 is a cross-sectional view of a display panel according to some embodiments;

FIG. 8 is an enlarged cross-sectional view of a portion of a display panel according to some embodiments;

FIGS. 9A and 9B are cross-sectional views illustrating processes of a method of manufacturing a display panel, according to some embodiments; and

FIGS. 10A and 10B are cross-sectional views illustrating processes of a method of manufacturing a display panel, according to some embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term "and/or" includes any and all combinations of one or more of the associated listed items. Throughout the disclosure, the expression "at least one of a, b, or c" indicates only a, only b, only c, both a and b, both a and c, both b and c, all of a, b, and c, or variations thereof.

As the disclosure allows for various changes and numerous embodiments, certain embodiments will be illustrated in the drawings and described in detail in the written description. Hereinafter, effects and features of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

One or more embodiments will be described below in more detail with reference to the accompanying drawings. Those components that are the same or are in correspondence are rendered the same reference numeral regardless of the figure number, and redundant descriptions thereof are omitted.

It will be understood that when a component, such as a layer, a film, a region, or a plate, is referred to as being "on" another component, the component can be directly on the other component or intervening components may be present therebetween. Sizes of elements in the drawings may be exaggerated or reduced for convenience of description. In other words, since sizes and thicknesses of components in the drawings are arbitrarily illustrated for convenience of explanation, the following embodiments are not limited thereto.

According to some embodiments below, terms, such as "first" and "second," are used herein merely to describe a variety of elements, but the elements are not limited by the terms. Such terms are used only for the purpose of distinguishing one element from another element.

According to some embodiments below, it will be further understood that the terms "comprises" and/or "comprising" used herein specify the presence of stated features or components, but do not preclude the presence or addition of one or more other features or components.

"A and/or B" as used herein may include "A," "B," or "A and B." In addition, "at least one of A and B" may include "A," "B," or "A and B."

In one or more embodiments described below, when it is described that a film, area, or component is connected, it includes not only a case where the films, areas, or components are directly connected, but also a case where other films, areas, or components are between the films, areas, or components and are indirectly connected. For example, when it is described herein that a film, area, or component, etc., is electrically connected, it includes not only cases where the film, area, or component, etc., are directly electrically connected, but also cases where another film, area, or component, etc. is located therebetween and indirectly electrically connected.

In one or more embodiments described below, the expression "x direction" may refer to a +x direction and a -x direction, i.e., a ±x direction. In one or more embodiments described below, the expression "y direction" may refer to a +y direction and a -y direction, i.e., a ±y direction. In one or more embodiments described below, the expression "z direction" may refer to a +z direction and a -z direction, i.e., a ±z direction.

A display device according to one or more embodiments may be applied to various electronic devices. An electronic device according to some embodiments includes a display device, and may further include a module or device having additional functions in addition to the display device. A display device according to some embodiments may include a display panel.

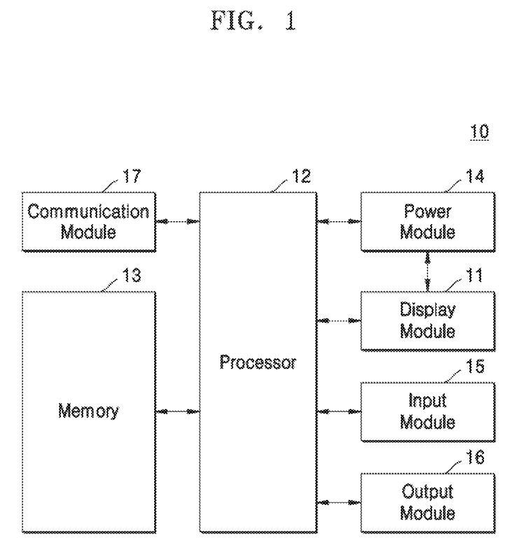

FIG. 1 is a block diagram of an electronic device 10 according to some embodiments. Referring to FIG. 1, the electronic device 10 may include a display panel 11, a processor 12, a memory 13, and a power module 14. Although FIG. 1 illustrates various components in an electronic device 10 according to some embodiments of the present disclosure, embodiments are not limited thereto, and according to various embodiments, the electronic device 10 may include additional components or fewer components without departing from the spirit and scope of embodiments according to the present disclosure.

The processor 12 may include at least one of a central processing unit (CPU), an application processor (AP), a graphics processing unit (GPU), a communication processor (CP), an image signal processor (ISP), or a controller. According to some embodiments, the processor 12 may include two or more parts from a functional or structural standpoint. For example, the processor 12 may include a main processor in the form of a first driving chip, including a CPU, and an auxiliary processor in the form of a second driving chip, including a controller which receives image signals from the main processor and processes the image signals to meet the interface specifications of the display panel 11.

The memory 13 may include at least one of non-volatile memory or volatile memory. The memory 13 may store data information necessary for operation of the processor 12 or display panel 11. When the processor 12 executes an application stored in the memory 13, image data signals and/or input control signals may be transmitted to the display panel 11, and the display panel 11 may process the received signals and output image information through a display screen.

The power module 14 may include a power supply module, such as a power adapter or a battery device, and a power conversion module which converts power supplied by the power supply module and generates power required for operation of the electronic device 10. Power conversion by the power conversion module may include, but is not limited to, direct current (DC)-DC conversion, alternating current (AC)-DC conversion, and DC-AC conversion.

The electronic device 10 may further include an input module 15, a non-video output module 16, and/or a communication module 17.

The input module 15 may provide input information to the processor 12 and/or the display panel 11. The input module 15 may include various sensor modules as well as physical buttons, keyboard, and microphone. Examples of sensor modules may include biometric sensors, such as blood pressure sensors, blood sugar sensors, electrocardiogram sensors, and heart rate sensors, as well as touch sensors, pressure sensors, distance sensors, position sensors, digitizers, motion recognition sensors, camera sensors, light-receiving sensors, photoelectric conversion sensors, and temperature sensors.

The non-video output module 16 may receive information other than an image from the processor 12 and provide the received information to the user. Examples of the non-video output module 16 include audio modules, haptic modules, light-emitting modules, etc., and may include other functional modules unique to the electronic device 10 (e.g., a cooling module in a refrigerator).

The communication module 17 is a module responsible for transmitting and receiving information between the electronic device 10 and an external device, and may include a reception unit and a transmission unit. The communication module 17 may include various wireless communication modules, such as a mobile communication module, a Wireless-Fidelity (Wi-Fi) module, a Bluetooth module, or various wired communication modules.

At least one of the components of the electronic device 10 described above may be included in the display device. In addition, some of individual modules functionally included within a module may be included within the display device, while others may be provided separately from the display device. For example, the display device may include the display panel 11, and the processor 12, the memory 13, and the power module 14 may be provided in the form of other devices within the electronic device 10 other than the display device. In another example, the power module 14 may be provided within the display device and may supply power to the processor 12 and memory 13 provided within the electronic device 10, which is not the display device. However, one or more embodiments are not limited to the examples described above.

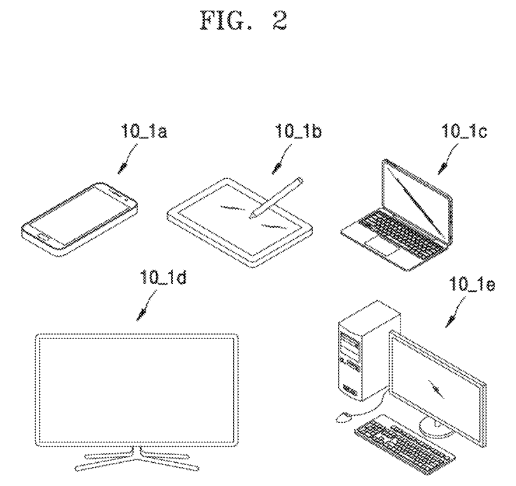

FIGS. 2 to 4 are schematic diagrams of an electronic device according to various embodiments. FIGS. 2 to 4 show examples of various electronic devices including display panels according to embodiments.

FIG. 2 illustrates examples of electronic devices such as a smartphone 10_1a, a tablet personal computer (PC) 10_1b, a laptop 10_1c, a television (TV) 10_1d, and a desk monitor 10_1e.

The smartphone 10_1a may include an input module, such as a touch sensor, and a communication module in addition to the display panel. The smartphone 10_1a may process information received through the communication module or other input modules and display the information on a display panel of a display device.

The tablet PC 10_1b, the laptop 10_1c, the TV 10_1d, and the desk monitor 10_1e may also include a display panel and an input module, similar to the smartphone 10_1a, and may further include a communication module in some cases.

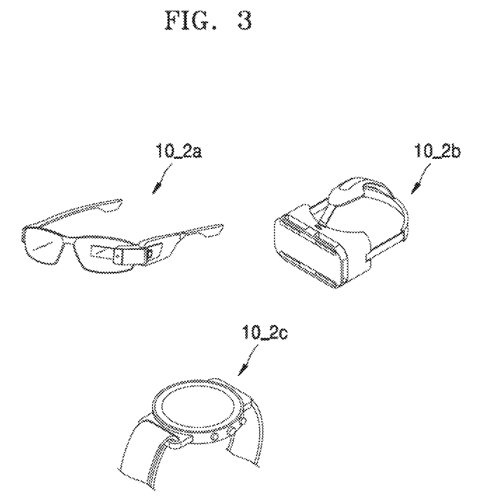

FIG. 3 shows an example in which an electronic device including a display panel is applied to a wearable electronic device. The wearable electronic device may be smart glasses 10_2a, a head mounted display 10_2b, a smart watch 10_2c, or the like.

The smart glasses 10_2a and the head mounted display 10_2b may include a display panel from which a display image is emitted, and a reflector which reflects the emitted display image and provides the reflected display image to user's eyes, thereby providing a virtual reality or augmented reality screen to the user.

The smart watch 10_2c may include a biometric sensor as an input device and may provide biometric information recognized by the biometric sensor to the user through a display panel.

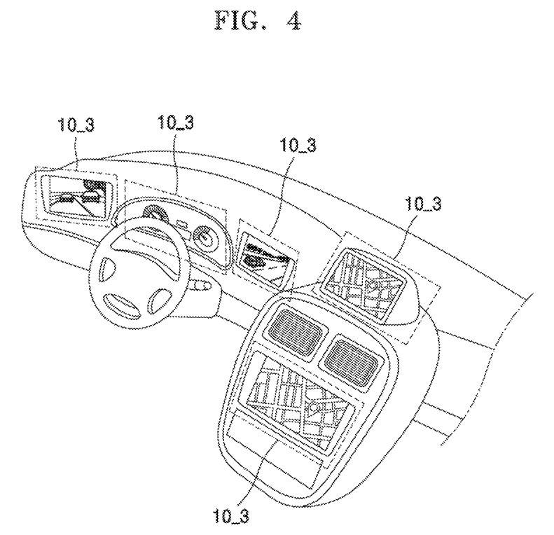

FIG. 4 illustrates an example in which an electronic device 10_3 including a display panel is applied to a vehicle. For example, the electronic device 10_3 may be applied to an instrument panel, center fascia, or the like of a vehicle, or may be applied to a center information display (CID) arranged on a dashboard of a vehicle, or to a room mirror display replacing a side-view mirror.

According to some embodiments, electronic devices to which display panels according to the embodiments are applied may include not only devices for mainly displaying screens, such as billboards, electronic boards, and game consoles, but also various home appliances which display information through display panels, such as refrigerators, washing machines, dryers, air conditioners, and robot vacuum cleaners. In addition, when the display panel has a function of transmitting light, the display panel may be applied to electronic devices, such as smart windows or transparent display devices which display a background and a display image together. Types of electronic devices according to the embodiments are not limited to the examples described above, and the display panel may be applied to various other electronic devices not described.

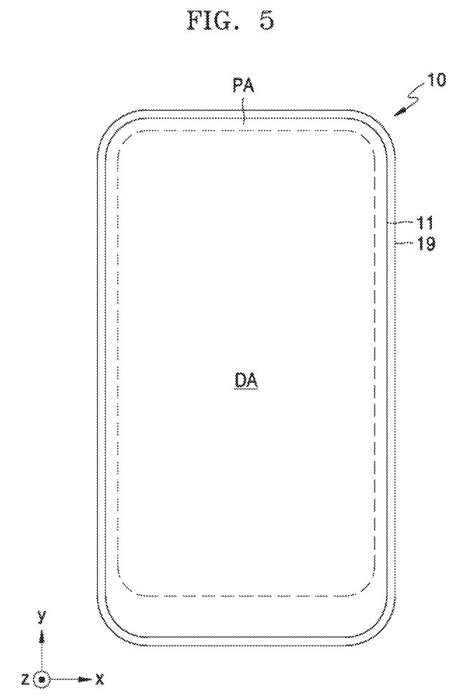

FIG. 5 is a schematic plan view of the electronic device 10 according to some embodiments.

FIG. 5 shows an example in which the electronic device 10 is a smartphone. However, this is only for convenience of explanation and one or more embodiments are not necessarily limited thereto. The electronic device 10 may include the display panel 11 and a housing 19. According to some embodiments, the display panel 11 may be accommodated within the housing 19. The housing 19 is not necessarily implemented in the form shown in FIG. 5, and may belong to the housing 19 referred to herein, without limitation in type or form, as long as the housing provides a space in which the display panel 11 may be accommodated. For example, the housing 19 may not need to entirely surround the display panel 11 and may only partially cover the display panel 11.

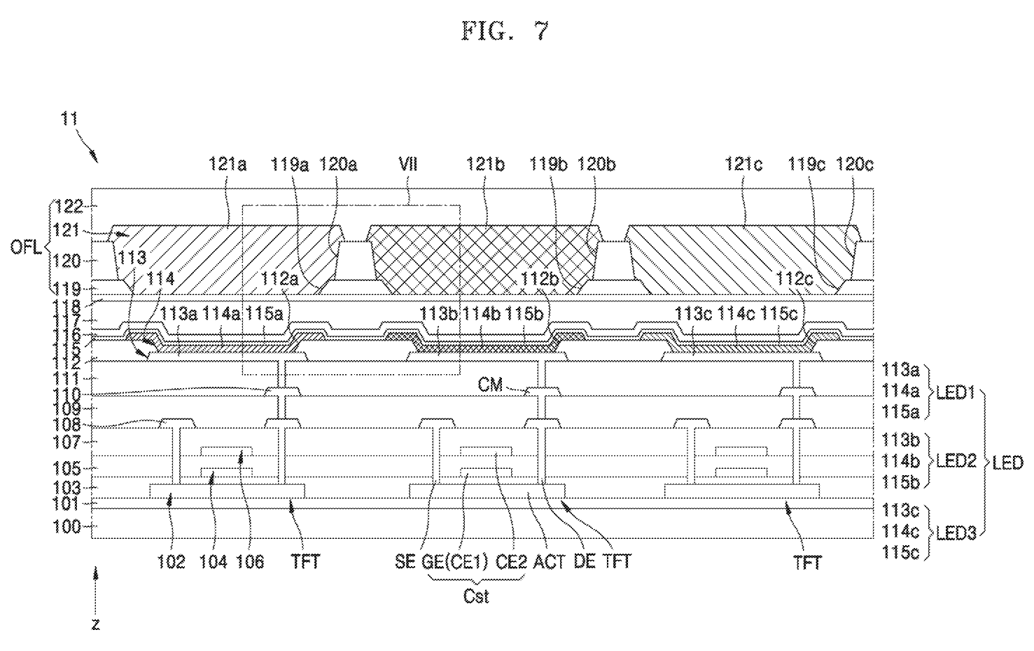

Referring to FIG. 5, the display panel 11 may include a display area DA and a peripheral area PA outside (e.g., surrounding, in a periphery, or outside a footprint of) the display area DA. In other words, the display area DA and the peripheral area PA outside (e.g., surrounding, in a periphery, or outside a footprint of) the display area DA may be defined in the display panel 11. In other words, the display panel 11 may include a substrate 100 (see FIG. 7), and the display area DA and the peripheral area PA may be defined on the substrate 100.

A pixel may be arranged in the display area DA. The pixel may include at least one light-emitting diode and a pixel circuit connected to the light-emitting diode to drive the light-emitting diode. The light-emitting diode driven by the pixel circuit may emit light of a certain color (i.e., wavelength). The display panel 11 may provide an image and/or video through light emitted from a plurality of light-emitting diodes provided in a plurality of pixels. According to some embodiments, the pixel may include a plurality of grouped subpixels. According to some embodiments, one subpixel may include one corresponding light-emitting diode and one subpixel circuit. According to some embodiments, light-emitting diodes respectively provided in a plurality of subpixels grouped into one pixel may emit light of different colors (i.e., wavelengths). The peripheral area PA is a non-display area, and a signal line and/or voltage line for driving the light-emitting diode may be arranged in the peripheral area PA.

FIG. 5 shows that the planar shapes of the display panel 11 and the display area DA are quadrilaterals (or approximately quadrilaterals) with round corners, but one or more embodiments are not necessarily limited thereto. The display panel 11 and/or the display area DA may have various planar shapes, such as other polygonal, circular, elliptical, or irregular shapes.

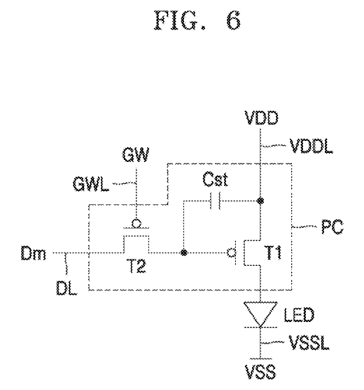

FIG. 6 is an equivalent circuit diagram of a pixel of a display panel according to some embodiments. Although FIG. 6 illustrates various components in a pixel according to some embodiments, embodiments according to the present disclosure are not limited thereto, and according to various embodiments, the pixel may include addition components without departing from the spirit and scope of embodiments according to the present disclosure.

Referring to FIG. 6, a light-emitting diode LED corresponding to the pixel may be electrically connected to a pixel circuit PC. The pixel circuit PC may include a first transistor T1, a second transistor T2, and a storage capacitor Cst. The pixel circuit PC may be electrically connected to a signal line and a voltage line. The signal line may include a scan signal line GWL and a data line DL, and the voltage line may include a first voltage line VDDL.

The second transistor T2 is a data write transistor and may be electrically connected to the scan signal line GWL and the data line DL. The scan signal line GWL may provide a scan signal GW to a gate of the second transistor T2. The second transistor T2 may transmit a data signal Dm input from the data line DL to the first transistor T1 in response to the scan signal GW input from the scan signal line GWL.

The storage capacitor Cst may be electrically connected to the second transistor T2 and the first voltage line VDDL, and may store a voltage corresponding to a voltage difference between a voltage received from the second transistor T2 and a first power supply voltage VDD supplied via the first voltage line VDDL.

The first transistor T1 is a driving transistor and may control a driving current flowing through the light-emitting diode LED. The first transistor T1 may be connected to the first voltage line VDDL and the storage capacitor Cst. The first transistor T1 may control the driving current flowing from the first voltage line VDDL to the light-emitting diode LED in response to the voltage value stored in the storage capacitor Cst. The light-emitting diode LED may emit light with a certain luminance according to the driving current. A first electrode (e.g., a pixel electrode or an anode) of the light-emitting diode LED may be electrically connected to the first transistor T1, and a second electrode (e.g., an opposite electrode or a cathode) may be electrically connected to a second voltage line VSSL for supplying a second power supply voltage VSS.

Although FIG. 6 shows that the pixel circuit PC includes one switching transistor (e.g., the second transistor T2) and one capacitor (e.g., the storage capacitor Cst), in other embodiments, the pixel circuit PC may include two or more switching transistors and/or two or more capacitors.

FIG. 7 is a cross-sectional view of the display panel 11 according to some embodiments. FIG. 7 may be a cross-sectional view of the display area DA (see FIG. 5) of the display panel 11.

Referring to FIG. 7, the light-emitting diode LED and a thin-film transistor TFT corresponding to each light-emitting diode LED may be arranged on the substrate 100. For example, a first light-emitting diode LED1, a second light-emitting diode LED2, and a third light-emitting diode LED3 may be arranged on the substrate 100, and corresponding thin-film transistors TFT may be arranged. The first light-emitting diode LED1, the second light-emitting diode LED2, and the third light-emitting diode LED3 may be connected to corresponding thin-film transistors TFT, respectively.

According to some embodiments, the first light-emitting diode LED1, the second light-emitting diode LED2, and the third light-emitting diode LED3 may each belong to a separate pixel or may belong to a single pixel. When the first light-emitting diode LED1, the second light-emitting diode LED2, and the third light-emitting diode LED3 belong to one pixel, each light-emitting diode LED may belong to a corresponding subpixel. The thin-film transistors TFT respectively connected to the first light-emitting diode LED1, the second light-emitting diode LED2, and the third light-emitting diode LED3 may correspond to a portion of the pixel circuit PC described above with reference to FIG. 6. For example, the thin-film transistor TFT may correspond to the first transistor T1 of FIG. 6.

A first insulating layer 101 may be arranged on the substrate 100. The first insulating layer 101 may entirely cover the substrate 100. The first insulating layer 101 may planarize and protect an upper surface of the substrate 100. The first insulating layer 101 may include an inorganic insulating material. According to some embodiments, the first insulating layer 101 may include at least one inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-or multi-layer structure of the materials described above. According to some embodiments, the first insulating layer 101 may be a buffer layer.

The thin-film transistor TFT may be arranged on the first insulating layer 101. The thin-film transistor TFT may include an active layer ACT, a gate electrode GE, a source electrode SE, and a drain electrode DE. Thin-film transistors TFT respectively corresponding to the first to third light-emitting diodes LED1, LED2, and LED3 may be arranged on the first insulating layer 101. Structures of thin-film transistors TFT respectively corresponding to the first to third light-emitting diodes LED1, LED2, and LED3 may be similar to each other.

A semiconductor layer 102 may be arranged on the first insulating layer 101. The semiconductor layer 102 may include the active layer ACT. The active layer ACT may be patterned to correspond to each thin-film transistor TFT. The active layer ACT may include a drain region overlapping the drain electrode DE, a source region overlapping the source electrode SE, and a channel region between the drain region and the source region. The drain region and the source region may be regions doped with impurities (i.e., dopants).

A second insulating layer 103 may be arranged on the semiconductor layer 102. The second insulating layer 103 may include an inorganic insulating material. According to some embodiments, the second insulating layer 103 may include at least one inorganic insulating material, such as SiO₂, SiNₓ, SiON, Al₂O₃, TiO₂, Ta₂O₅, HfO₂, and ZnO₂, and may have a single-or multi-layer structure of the materials described above. According to some embodiments, the second insulating layer 103 may be a first gate insulating layer. According to some embodiments, as shown in FIG. 7, the second insulating layer 103 may entirely cover the semiconductor layer 102 and the first insulating layer 101. According to some embodiments, the second insulating layer 103 may be patterned to cover only each active layer ACT and not an upper surface of the first insulating layer 101 between the active layers ACT. According to some embodiments, the second insulating layer 103 may be patterned to cover only a portion of each active layer ACT (e.g., a region overlapping the gate electrode GE, i.e., the channel region).

The storage capacitor Cst may be arranged on the second insulating layer 103. The storage capacitor Cst may include a first capacitor electrode CE1 and a second capacitor electrode CE2. The second capacitor electrode CE2 may be arranged on the first capacitor electrode CE1.

A first conductive layer 104 may be arranged on the second insulating layer 103. The first conductive layer 104 may include the gate electrode GE and the first capacitor electrode CE1. The gate electrode GE may be patterned to correspond to each thin-film transistor TFT. The gate electrode GE may overlap the channel region of the active layer ACT. The first capacitor electrode CE1 may be patterned to correspond to each storage capacitor Cst. According to some embodiments, the gate electrode GE and the first capacitor electrode CE1 may be integrally provided as one body, as shown in FIG. 7. According to some embodiments, the gate electrode GE and the first capacitor electrode CE1 may be provided separately. According to some embodiments, the first conductive layer 104 may include at least one of aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and may have a single- or multi-layer structure of the materials described above.

A third insulating layer 105 may be arranged on the first conductive layer 104. The third insulating layer 105 may entirely cover the first conductive layer 104. The third insulating layer 105 may include an inorganic insulating material. According to some embodiments, the third insulating layer 105 may include at least one inorganic insulating material, such as SiO₂, SiNₓ, SiON, Al₂O₃, TiO₂, Ta₂O₅, HfO₂, and ZnO₂, and may have a single-or multi-layer structure of the materials described above. According to some embodiments, the third insulating layer 105 may be a second gate insulating layer.

A second conductive layer 106 may be arranged on the third insulating layer 105. The second conductive layer 106 may include the second capacitor electrode CE2 of each storage capacitor Cst. The second capacitor electrode CE2 may be patterned to correspond to each storage capacitor Cst. The second capacitor electrode CE2 may overlap the first capacitor electrode CE1. According to some embodiments, the second conductive layer 106 may include at least one of Al, Pt, Pd, Ag, Mg, Au, Ni, Nd, Ir, Cr, Ca, Mo, Ti, W, and/or Cu, and may have a single- or multi-layer structure of the materials described above.

A fourth insulating layer 107 may be arranged on the second conductive layer 106. The fourth insulating layer 107 may entirely cover the second conductive layer 106. The fourth insulating layer 107 may include an inorganic insulating material. According to some embodiments, the fourth insulating layer 107 may include at least one inorganic insulating material, such as SiO₂, SiNₓ, SiON, Al₂O₃, TiO₂, Ta₂O₅, HfO₂, and ZnO₂, and may have a single-or multi-layer structure of the materials described above. According to some embodiments, the fourth insulating layer 107 may be an interlayer insulating layer.

A third conductive layer 108 may be arranged on the fourth insulating layer 107. The third conductive layer 108 may include the source electrode SE and the drain electrode DE of each thin-film transistor TFT. The source electrode SE and drain electrode DE may be patterned to correspond to each thin-film transistor TFT. The source electrode SE may overlap the source region of the active layer ACT. The drain electrode DE may overlap the drain region of the active layer ACT. The source electrode SE may be connected to the active layer ACT (e.g., to the source region of the active layer ACT) through an opening defined in the second to fourth insulating layers 103, 105, and 107. The drain electrode DE may be connected to the active layer ACT (e.g., to the drain region of the active layer ACT) through an opening defined in the second to fourth insulating layers 103, 105, and 107. According to some embodiments, the third conductive layer 108 may include at least one of Al, Pt, Pd, Ag, Mg, Au, Ni, Nd, Ir, Cr, Ca, Mo, Ti, W, and/or Cu, and may have a single- or multi-layer structure of the materials described above.

A fifth insulating layer 109 may be arranged on the third conductive layer 108. In the fifth insulating layer 109, an opening overlapping the drain electrode DE may be defined. The fifth insulating layer 109 may include an organic insulating material. According to some embodiments, the fifth insulating layer 109 may include an organic insulating material, such as a general-purpose polymer such as benzocyclobutene, polyimide, hexamethyldisiloxane, polymethylmethacrylate, or polystyrene, a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer, and may have a single- or multi-layer structure of the materials described above. According to some embodiments, the fifth insulating layer 109 may be a first via layer.

A fourth conductive layer 110 may be arranged on the fifth insulating layer 109. The fourth conductive layer 110 may include contact metals CM corresponding to the first to third light-emitting diodes LED1, LED2, and LED3. The contact metal CM may be patterned to overlap the corresponding light-emitting diode LED. The contact metal CM may be connected to the corresponding drain electrode DE through an opening defined in the fifth insulating layer 109. According to some embodiments, the fourth conductive layer 110 may include at least one of Al, Pt, Pd, Ag, Mg, Au, Ni, Nd, Ir, Cr, Ca, Mo, Ti, W, and/or Cu, and may have a single- or multi-layer structure of the materials described above.

A sixth insulating layer 111 may be arranged on the fourth conductive layer 110. Openings overlapping the respective contact metals CM of the fourth conductive layer 110 may be defined in the sixth insulating layer 111. The sixth insulating layer 111 may include an organic insulating material. According to some embodiments, the sixth insulating layer 111 may include an organic insulating material, such as a general-purpose polymer such as benzocyclobutene, polyimide, hexamethyldisiloxane, polymethylmethacrylate, or polystyrene, a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer, and may have a single- or multi-layer structure of the materials described above. According to some embodiments, the sixth insulating layer 111 may be a second via layer.

A plurality of light-emitting diodes LED may be arranged on the sixth insulating layer 111. According to some embodiments, the first to third light-emitting diodes LED1, LED2, and LED3 may be arranged on the sixth insulating layer 111. Each light-emitting diode LED may include a corresponding pixel electrode, intermediate layer, and opposite electrode. According to some embodiments, the first light-emitting diode LED1 may include a first pixel electrode 113a, a first intermediate layer 114a, and a first opposite electrode 115a. According to some embodiments, the second light-emitting diode LED2 may include a second pixel electrode 113b, a second intermediate layer 114b, and a second opposite electrode 115b. According to some embodiments, the third light-emitting diode LED3 may include a third pixel electrode 113c, a third intermediate layer 114c, and a third opposite electrode 115c. The intermediate layer of each light-emitting diode LED may emit light through current flowing in the intermediate layer due to a potential difference between the pixel electrode and the opposite electrode, and thus the light-emitting diode LED may emit light.

A fifth conductive layer 113 may be arranged on the sixth insulating layer 111. The fifth conductive layer 113 may include the first pixel electrode 113a, the second pixel electrode 113b, and the third pixel electrode 113c. The first pixel electrode 113a, the second pixel electrode 113b, and the third pixel electrode 113c may be individually patterned and spaced apart from each other. Each of the first pixel electrode 113a, the second pixel electrode 113b, and the third pixel electrode 113c may be connected to the corresponding thin-film transistor TFT through the corresponding contact metal CM and drain electrode DE. According to some embodiments, the fifth conductive layer 113 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to some embodiments, the fifth conductive layer 113 may include a reflective film including Ag, Mg, Al, Pt, Pd, Au, Ni, Nd, Ir, Cr, or compounds thereof. However, a composition and materials of the fifth conductive layer 113 are not limited thereto and various modifications are possible.

A pixel-defining layer 112 may be arranged on the fifth conductive layer 113 and the sixth insulating layer 111. The pixel-defining layer 112 may include a plurality of light-emitting openings overlapping a plurality of pixel electrodes of the fifth conductive layer 113. In other words, the pixel-defining layer 112 may cover an edge (or edge area) of each pixel electrode of the fifth conductive layer 113.

According to some embodiments, the pixel-defining layer 112 may include a first light-emitting opening 112a overlapping the first pixel electrode 113a. In other words, the pixel-defining layer 112 may cover an edge (or edge area) of the first pixel electrode 113a. According to some embodiments, sides of the pixel-defining layer 112 defining the first light-emitting opening 112a may be tapered. According to some embodiments, an angle of the taper of the pixel-defining layer 112 defining the first light-emitting opening 112a may be 90° (or about 90°) or less. In other words, a size (e.g., width) of the first light-emitting opening 112a may increase along the +z direction.

According to some embodiments, the pixel-defining layer 112 may include a second light-emitting opening 112b overlapping the second pixel electrode 113b. In other words, the pixel-defining layer 112 may cover an edge (or edge area) of the second pixel electrode 113b. According to some embodiments, sides of the pixel-defining layer 112 defining the second light-emitting opening 112b may be tapered. According to some embodiments, an angle of the taper of the pixel-defining layer 112 defining the second light-emitting opening 112b may be 90° (or about 90°) or less. In other words, a size (e.g., width) of the second light-emitting opening 112b may increase along the +z direction.

According to some embodiments, the pixel-defining layer 112 may include a third light-emitting opening 112c overlapping the third pixel electrode 113c. In other words, the pixel-defining layer 112 may cover an edge (or edge area) of the third pixel electrode 113c. According to some embodiments, sides of the pixel-defining layer 112 defining the third light-emitting opening 112c may be tapered. According to some embodiments, an angle of the taper of the pixel-defining layer 112 defining the third light-emitting opening 112c may be 90° (or about 90°) or less. In other words, a size (e.g., width) of the third light-emitting opening 112c may increase along the +z direction.

An intermediate layer 114 may be arranged (e.g., deposited) on the pixel-defining layer 112 and the fifth conductive layer 113. The intermediate layer 114 may include the first intermediate layer 114a, the second intermediate layer 114b, and the third intermediate layer 114c.

According to some embodiments, the intermediate layer 114 may include an emission layer and a functional layer. The emission layer may include a low-molecular weight or polymer material which emits light when a certain voltage is applied (or a certain current flows). The functional layer may include at least one of an electron transport layer (ETL), an electron injection layer (EIL), a hole transport layer (HTL), or a hole injection layer (HIL). The first intermediate layer 114a, the second intermediate layer 114b, and the third intermediate layer 114c may each include an emission layer and a functional layer.

According to some embodiments, the emission layers respectively included in the first intermediate layer 114a, the second intermediate layer 114b, and the third intermediate layer 114c may include different materials. In other words, the emission layers respectively included in the first intermediate layer 114a, the second intermediate layer 114b, and the third intermediate layer 114c may emit light of different colors (i.e., wavelengths). According to some embodiments, the emission layer included in the first intermediate layer 114a may emit red light when current flows. According to some embodiments, the emission layer included in the second intermediate layer 114b may emit green light when current flows. According to some embodiments, the emission layer included in the third intermediate layer 114c may emit blue light when current flows.

The first intermediate layer 114a may overlap the first pixel electrode 113a. According to some embodiments, a portion (e.g., a first portion) of the first intermediate layer 114a may be arranged in the first light-emitting opening 112a of the pixel-defining layer 112, and may be in contact with the first pixel electrode 113a. According to some embodiments, another portion (e.g., the second portion) of the first intermediate layer 114a may be arranged on the pixel-defining layer 112. According to some embodiments, the first portion and the second portion of the first intermediate layer 114a may be connected to each other. In other words, the first intermediate layer 114a may cover an edge of the pixel-defining layer 112 which defines the first light-emitting opening 112a. According to some embodiments, the first intermediate layer 114a may be arranged entirely in the first light-emitting opening 112a. According to some embodiments, the emission layer of the first intermediate layer 114a may be arranged within the first light-emitting opening 112a, and the functional layer of the first intermediate layer 114a may extend outside the first light-emitting opening 112a.

The second intermediate layer 114b may overlap the second pixel electrode 113b. According to some embodiments, a portion (e.g., a first portion) of the second intermediate layer 114b may be arranged in the second light-emitting opening 112b of the pixel-defining layer 112, and may be in contact with the second pixel electrode 113b. According to some embodiments, another portion (e.g., the second portion) of the second intermediate layer 114b may be arranged on the pixel-defining layer 112. According to some embodiments, the first portion and the second portion of the second intermediate layer 114b may be connected to each other. In other words, the second intermediate layer 114b may cover an edge of the pixel-defining layer 112 which defines the second light-emitting opening 112b. According to some embodiments, the second intermediate layer 114b may be arranged entirely in the second light-emitting opening 112b. According to some embodiments, the emission layer of the second intermediate layer 114b may be arranged in the second light-emitting opening 112b, and the functional layer of the second intermediate layer 114b may extend outside the second light-emitting opening 112b.

The third intermediate layer 114c may overlap the third pixel electrode 113c. According to some embodiments, a portion (e.g., a first portion) of the third intermediate layer 114c may be arranged in the third light-emitting opening 112c of the pixel-defining layer 112, and may be in contact with the third pixel electrode 113c. According to some embodiments, another portion (e.g., the second portion) of the third intermediate layer 114c may be arranged on the pixel-defining layer 112. According to some embodiments, the first portion and the second portion of the third intermediate layer 114c may be connected to each other. In other words, the third intermediate layer 114c may cover an edge of the pixel-defining layer 112 which defines the third light-emitting opening 112c. According to some embodiments, the third intermediate layer 114c may be arranged entirely in the third light-emitting opening 112c. According to some embodiments, the emission layer of the third intermediate layer 114c may be arranged in the third light-emitting opening 112c, and the functional layer of the third intermediate layer 114c may extend outside the third light-emitting opening 112c.

An opposite electrode 115 may be arranged on the intermediate layer 114. The opposite electrode 115 may be integrally formed as one body across the first to third light-emitting diodes LED1, LED2, and LED3. The opposite electrode 115 may cover the intermediate layer 114. A portion of the opposite electrode 115 overlapping the first intermediate layer 114a may be considered as the first opposite electrode 115a. According to some embodiments, the first opposite electrode 115a may cover the first intermediate layer 114a. A portion of the opposite electrode 115 overlapping the second intermediate layer 114b may be considered as the second opposite electrode 115b. According to some embodiments, the second opposite electrode 115b may cover the second intermediate layer 114b. A portion of the opposite electrode 115 overlapping the third intermediate layer 114c may be considered as the third opposite electrode 115c. According to some embodiments, the third opposite electrode 115c may cover the third intermediate layer 114c.

The opposite electrode 115 may include a conductive material. According to some embodiments, the opposite electrode 115 may include a transparent layer (or a translucent layer) including Ag, Mg, Al, Pt, Pd, Au, Ni, Nd, Ir, Cr, lithium (Li), calcium (Ca), or an alloy thereof. Alternatively, the opposite electrode 115 may further include a layer including a material, such as ITO, IZO, ZnO, or In₂O₃, on the transparent layer (or translucent layer) including the materials described above.

A thin-film encapsulation layer TFEL may be arranged on the opposite electrode 115. The thin-film encapsulation layer TFEL may entirely cover the opposite electrode 115. The thin-film encapsulation layer TFEL may include at least one inorganic encapsulation layer and at least one organic encapsulation layer. According to some embodiments, the thin-film encapsulation layer TFEL may include a first inorganic encapsulation layer 116, a second inorganic encapsulation layer 118, and an organic encapsulation layer 117 between the first inorganic encapsulation layer 116 and the second inorganic encapsulation layer 118. According to some embodiments, the first inorganic encapsulation layer 116 may entirely cover the opposite electrode 115. According to some embodiments, the organic encapsulation layer 117 may be provided as a planarization layer.

According to some embodiments, the first inorganic encapsulation layer 116 and/or the second inorganic encapsulation layer 118 may include at least one inorganic insulating material, such as SiO₂, SiNₓ, SiON, Al₂O₃, TiO₂, Ta₂O₅, HfO₂, and ZnO₂. The organic encapsulation layer 117 may include an organic insulating material. According to some embodiments, the organic encapsulation layer 117 may include a polymer-based material. Examples of polymer-based materials include silicone-based resins, acryl-based resins, epoxy-based resins, polyimides, and polyethylene. One or more embodiments are not necessarily limited to the thin-film encapsulation layer TFEL with the structure described above, and the number and stacking order of at least one inorganic encapsulation layer and at least one organic encapsulation layer may be variously modified.

According to some embodiments, a touch input layer may be arranged on the thin-film encapsulation layer TFEL (e.g., between the thin-film encapsulation layer TFEL and an optical functional layer OFL). The touch input layer may detect an external input, such as a touch from an object such as a finger or a pen, so that the display panel 11 may obtain coordinate information corresponding to the touch location. The touch input layer may include at least one conductive layer and at least one insulating layer. The conductive layer of the touch input layer may be arranged between adjacent insulating layers. The conductive layer of the touch input layer may include a touch electrode and signal lines connected to the touch electrode. The touch input layer may detect an external input by using a mutual capacitance method or a self-capacitance method.

The optical functional layer OFL may be arranged on the thin-film encapsulation layer TFEL (or touch input layer). The optical functional layer OFL may include a first light-shielding layer 119, a second light-shielding layer 120, a color filter layer 121, and an overcoat layer 122.

The first light-shielding layer 119 may be arranged on the thin-film encapsulation layer TFEL. The first light-shielding layer 119 may overlap the pixel-defining layer 112. The first light-shielding layer 119 may include a plurality of first openings 119a, 119b, and 119c overlapping the respective light-emitting diodes LED. According to some embodiments, the first light-shielding layer 119 may include the first-1 opening 119a overlapping the first light-emitting diode LED1. The first-1 opening 119a defined in the first light-shielding layer 119 may overlap the first light-emitting opening 112a defined in the pixel-defining layer 112. According to some embodiments, the first light-shielding layer 119 may include a first-2 opening 119b overlapping the second light-emitting diode LED2. The first-2 opening 119b defined in the first light-shielding layer 119 may overlap the second light-emitting opening 112b defined in the pixel-defining layer 112. According to some embodiments, the first light-shielding layer 119 may include a first-3 opening 119c overlapping the third light-emitting diode LED3. The first-3 opening 119c defined in the first light-shielding layer 119 may overlap the third light-emitting opening 112c defined in the pixel-defining layer 112. According to some embodiments, the first light-shielding layer 119 may include a light-blocking material (e.g., black dye). According to some embodiments, the first light-shielding layer 119 may include a lyophilic material. According to some embodiments, the first light-shielding layer 119 may include a liquid-repellent material.

The second light-shielding layer 120 may be arranged on the first light-shielding layer 119. The first light-shielding layer 119, the second light-shielding layer 120, and the pixel-defining layer 112 may overlap each other. The second light-shielding layer 120 may include a plurality of second openings 120a, 120b, and 120c overlapping the respective light-emitting diode LEDs. The plurality of second openings 120a, 120b, and 120c defined in the second light-shielding layer 120 may overlap the plurality of first openings 119a, 119b, and 119c defined in the first light-shielding layer 119. According to some embodiments, the second light-shielding layer 120 may include the second-1 opening 120a overlapping the first light-emitting diode LED1. The first-1 opening 119a defined in the first light-shielding layer 119, the second-1 opening 120a defined in the second light-shielding layer 120, and the first light-emitting opening 112a defined in the pixel-defining layer 112 may overlap each other. According to some embodiments, the second light-shielding layer 120 may include the second-2 opening 120b overlapping the second light-emitting diode LED2. The first-2 opening 119b defined in the first light-shielding layer 119, the second-2 opening 120b defined in the second light-shielding layer 120, and the second light-emitting opening 112b defined in the pixel-defining layer 112 may overlap each other. According to some embodiments, the second light-shielding layer 120 may include the second-3 opening 120c overlapping the third light-emitting diode LED3. The first-3 opening 119c defined in the first light-shielding layer 119, the second-3 opening 120c defined in the second light-shielding layer 120, and the third light-emitting opening 112c defined in the pixel-defining layer 112 may overlap each other. According to some embodiments, the second light-shielding layer 120 may include a light-blocking material (e.g., black dye). According to some embodiments, the second light-shielding layer 120 may include a liquid-repellent material.

The color filter layer 121 may be arranged on the second light-shielding layer 120. The color filter layer 121 may include a plurality of color filters 121a, 121b, and 121c corresponding to the respective light-emitting diodes LED. The plurality of color filters 121a, 121b, and 121c may overlap the plurality of first openings 119a, 119b, and 119c defined in the first light-shielding layer 119, and the plurality of second openings 120a, 120b, and 120c defined in the second light-shielding layer 120.

According to some embodiments, the first color filter 121a may at least partially (e.g., entirely) fill the first-1 opening 119a defined in the first light-shielding layer 119 and the second-1 opening 120a defined in the second light-shielding layer 120. According to some embodiments, the first color filter 121a may cover sides and edges of the first light-shielding layer 119 defining the first-1 opening 119a. According to some embodiments, the first color filter 121a may cover sides and edges of the second light-shielding layer 120 defining the second-1 opening 120a. According to some embodiments, the first color filter 121a may transmit light having a wavelength corresponding to light emitted from the first light-emitting diode LED1. Thus, the light emitted from the first light-emitting diode LED1 may pass through the first color filter 121a, and light of other wavelengths may not pass through the first color filter 121a.

According to some embodiments, the second color filter 121b may at least partially (e.g., entirely) fill the first-2 opening 119b defined in the first light-shielding layer 119 and the second-2 opening 120b defined in the second light-shielding layer 120. According to some embodiments, the second color filter 121b may cover sides and edges of the first light-shielding layer 119 defining the first-2 opening 119b. According to some embodiments, the second color filter 121b may cover sides and edges of the second light-shielding layer 120 defining the second-2 opening 120b. According to some embodiments, the second color filter 121b may transmit light having a wavelength corresponding to light emitted from the second light-emitting diode LED2. Thus, the light emitted from the second light-emitting diode LED2 may pass through the second color filter 121b, and light of other wavelengths may not pass through the second color filter 121b.

According to some embodiments, the third color filter 121c may at least partially (e.g., entirely) fill the first-3 opening 119c defined in the first light-shielding layer 119 and the second-3 opening 120c defined in the second light-shielding layer 120. According to some embodiments, the third color filter 121c may cover sides and edges of the first light-shielding layer 119 defining the first-3 opening 119c. According to some embodiments, the third color filter 121c may cover sides and edges of the second light-shielding layer 120 defining the second-3 opening 120c. According to some embodiments, the third color filter 121c may transmit light having a wavelength corresponding to light emitted from the third light-emitting diode LED3. Thus, the light emitted from the third light-emitting diode LED3 may pass through the third color filter 121c, and light of other wavelengths may not pass through the third color filter 121c.

The overcoat layer 122 may be arranged on the color filter layer 121. The overcoat layer 122 may entirely cover the color filter layer 121, e.g., the plurality of color filters 121a, 121b, and 121c. According to some embodiments, the overcoat layer 122 may include a light-transmitting material. According to some embodiments, the overcoat layer 122 may be provided as a planarization layer.

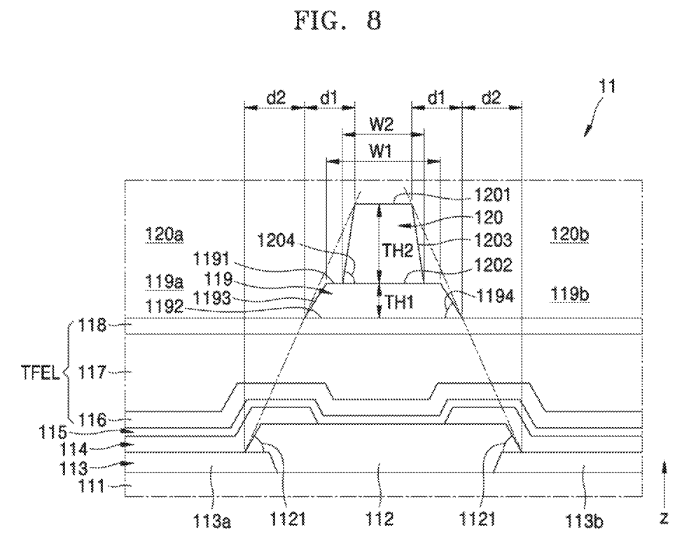

FIG. 8 is an enlarged cross-sectional view of a portion of the display panel 11 according to some embodiments. FIG. 8 may be an enlarged view of region VII in FIG. 7.

Hereinafter, features of the display panel 11 are described in detail with reference to region VII, the first-1 opening 119a, the first-2 opening 119b, the second-1 opening 120a, the second-2 opening 120b, and a portion of the first light-shielding layer 119 and the second light-shielding layer 120 arranged therebetween. However, it is noted that the features described below can be applied to the display panel 11 in general. In FIG. 8, the color filter layer 121 (see FIG. 7) is omitted for convenience of illustration and description.

Referring to FIG. 8, a portion of the first light-shielding layer 119 may be arranged between the first-1 opening 119a and the first-2 opening 119b, and a portion of the second light-shielding layer 120 may be arranged between the second-1 opening 120a and the second-2 opening 120b.

The first light-shielding layer 119 may include a first upper surface 1191, a first lower surface 1192, and a first side surface 1193 extending between the first upper surface 1191 and the first lower surface 1192 and connecting the first upper surface 1191 and the first lower surface 1192 to each other. According to some embodiments, the first upper surface 1191 may be a surface directed to the +z direction. According to some embodiments, the first lower surface 1192 may be an opposite surface of the first upper surface 1191, e.g., a surface directed to the -z direction. According to some embodiments, the first lower surface 1192 may be in contact with an upper surface of the thin-film encapsulation layer TFEL, e.g., an upper surface of the second inorganic encapsulation layer 118. According to some embodiments, the first lower surface 1192 may be in contact with an upper surface of a touch input layer arranged between the first light-shielding layer 119 and the thin-film encapsulation layer TFEL. According to some embodiments, the first-1 opening 119a and the first-2 opening 119b may be defined by the first side surface 1193. According to some embodiments, the first upper surface 1191 and the first lower surface 1192 may be parallel to each other.

The second light-shielding layer 120 may include a second upper surface 1201, a second lower surface 1202, and a second side surface 1203 extending between the second upper surface 1201 and the second lower surface 1202 and connecting the second upper surface 1201 and the second lower surface 1202 to each other. According to some embodiments, the second upper surface 1201 may be a surface directed to the +z direction. According to some embodiments, the second lower surface 1202 may be an opposite surface of the second upper surface 1201, e.g., a surface directed to the -z direction. According to some embodiments, the second lower surface 1202 may contact an upper surface of the first light-shielding layer 119, e.g., the first upper surface 1191. According to some embodiments, the first upper surface 1191 and the second lower surface 1202 may be in direct contact with each other. According to some embodiments, the second-1 opening 120a and the second-2 opening 120b may be defined by the second side surface 1203. According to some embodiments, the second upper surface 1201 and the second lower surface 1202 may be parallel to each other. According to some embodiments, the first upper surface 1191, the first lower surface 1192, the second upper surface 1201, and the second lower surface 1202 may be parallel to each other.

The first light-shielding layer 119 may have a first thickness TH1. According to some embodiments, a distance between the first upper surface 1191 and the first lower surface 1192 of the first light-shielding layer 119 (e.g. in the z direction) may be defined as the first thickness TH1. According to some embodiments, the first thickness TH1 may be 2 (or about 2) micrometers (μm) or less.

The second light-shielding layer 120 may have a second thickness TH2. According to some embodiments, a distance (e.g. in the z direction) between the second upper surface 1201 and the second lower surface 1202 of the second light-shielding layer 120 may be defined as the second thickness TH2. According to some embodiments, the second thickness TH2 may be 5 (or about 5) μm or less. According to some embodiments, the second thickness TH2 may be 4 (or about 4) μm or less.

A width of the first light-shielding layer 119 may be greater than a width of the second light-shielding layer 120. According to some embodiments, a width of the first upper surface 1191 of the first light-shielding layer 119 may be less than a width of the first lower surface 1192. According to some embodiments, a width of the second upper surface 1201 of the second light-shielding layer 120 may be less than a width of the second lower surface 1202. According to some embodiments, the first upper surface 1191 of the first light-shielding layer 119 may have a first width W1. According to some embodiments, the second lower surface 1202 of the second light-shielding layer 120 may have a second width W2. According to some embodiments, the second width W2 may be less than the first width W1.

The first lower surface 1192 and the first side surface 1193 of the first light-shielding layer 119 may form a first angle 1194. According to some embodiments, the first side surface 1193 of the first light-shielding layer 119 and the upper surface of the second inorganic encapsulation layer 118 may form the first angle 1194. According to some embodiments, the first side surface 1193 of the first light-shielding layer 119 and an upper surface of the pixel-defining layer 112 may form the first angle 1194. In other words, the first light-shielding layer 119 may have a tapered first side surface 1193, and a taper angle of the first light-shielding layer 119 may be the first angle 1194. According to some embodiments, the first angle 1194 may be 55° (or about 55°) or less. Accordingly, the width of the first upper surface 1191 may be less than the width of the first lower surface 1192.

The second lower surface 1202 and the second side surface 1203 of the second light-shielding layer 120 may form a second angle 1204. According to some embodiments, the second side surface 1203 of the second light-shielding layer 120 and the first upper surface 1191 of the first light-shielding layer 119 may form the second angle 1204. According to some embodiments, the second side surface 1203 of the second light-shielding layer 120 and the upper surface of the pixel-defining layer 112 may form the second angle 1204. In other words, the second light-shielding layer 120 may have a tapered second side surface 1203, and a taper angle of the second light-shielding layer 120 may be the second angle 1204. According to some embodiments, the second angle 1204 may be 90° (or about 90°) or less. Accordingly, the width of the second upper surface 1201 may be less than the width of the second lower surface 1202.

A distance between an edge of the first lower surface 1192 of the first light-shielding layer 119 and an edge of the second upper surface 1201 of the second light-shielding layer 120 may be defined as a first distance d1. For example, a distance between an edge where the first side surface 1193 and the first lower surface 1192 of the first light-shielding layer 119 meet and an edge where the second side surface 1203 and the second upper surface 1201 of the second light-shielding layer 120 meet may be defined as the first distance d1. The first distance d1 may be a distance measured between the edges in a direction parallel to the first lower surface 1192, the first upper surface 1191, the second lower surface 1202, and/or the second upper surface 1201 (e.g., a direction perpendicular to the z direction). According to some embodiments, the first distance d1 may be 4.5 (or about 4.5) μm or less.

A distance between the edge of the first lower surface 1192 of the first light-shielding layer 119 and the edge of the pixel-defining layer 112 may be defined as a second distance d2. For example, a distance between the edge where the first side surface 1193 and the first lower surface 1192 of the first light-shielding layer 119 meet and an edge of the pixel-defining layer 112 in contact with an upper surface of the fifth conductive layer 113 (e.g., the first pixel electrode 113a or the second pixel electrode 113b) may be defined as the second distance d2. The second distance d2 may be a distance measured between the edges in a direction parallel to the first lower surface 1192, the first upper surface 1191, the second lower surface 1202, and/or the second upper surface 1201 (e.g., a direction perpendicular to the z direction). According to some embodiments, the second distance d2 may be from 4 (or about 4) μm to 6 (or about 6) μm.

According to some embodiments, an angle formed by a straight line connecting the edge of the pixel-defining layer 112 in contact with the upper surface of the fifth conductive layer 113 (e.g., the first pixel electrode 113a or the second pixel electrode 113b) and the edge of the first lower surface 1192 of the first light-shielding layer 119 with the upper surface of the fifth conductive layer 113 (e.g., the first pixel electrode 113a or the second pixel electrode 113b) may be defined as a third angle 1121. According to some embodiments, an angle formed by a straight line connecting the edge of the pixel-defining layer 112 in contact with the upper surface of the fifth conductive layer 113 (e.g., the first pixel electrode 113a or the second pixel electrode 113b) and the edge of the second upper surface 1201 of the second light-shielding layer 120 with the upper surface of the fifth conductive layer 113 (e.g., the first pixel electrode 113a or the second pixel electrode 113b) may be defined as the third angle 1121. According to some embodiments, the edge of the pixel-defining layer 112 in contact with the upper surface of the fifth conductive layer 113 (e.g., the first pixel electrode 113a or the second pixel electrode 113b), the edge of the first lower surface 1192 of the first light-shielding layer 119, and the edge of the second upper surface 1201 of the second light-shielding layer 120 may be located on a single straight line, and an angle formed by the straight line with the upper surface of the fifth conductive layer 113 (e.g., the first pixel electrode 113a or the second pixel electrode 113b) may be defined as the third angle 1121. According to some embodiments, the third angle 1121 may be between 55° (or about) 55° and 65° (or about) 65°.

FIG. 8 shows embodiments in which the edge of a pixel-defining layer 112 in contact with the upper surface of the fifth conductive layer 113 (e.g., the first pixel electrode 113a or the second pixel electrode 113b), the edge of the first lower surface 1192 of the first light-shielding layer 119, and the edge of the second upper surface 1201 of the second light-shielding layer 120 are on a single straight line (shown as a dashed-dotted line). However, one or more embodiments are not limited to the arrangement described above.

According to some embodiments, the edge of the pixel-defining layer 112 in contact with the upper surface of the fifth conductive layer 113 (e.g., the first pixel electrode 113a or the second pixel electrode 113b) and the edge of the first lower surface 1192 of the first light-shielding layer 119 may be located on a single straight line, and the edge of the second upper surface 1201 of the second light-shielding layer 120 may be located inside the straight line. In other words, the edge of the second upper surface 1201 of the second light-shielding layer 120 may not touch or overlap the straight line described above.

According to some embodiments, the edge of the pixel-defining layer 112 in contact with the upper surface of the fifth conductive layer 113 (e.g., the first pixel electrode 113a or the second pixel electrode 113b) and the edge of the second upper surface 1201 of the second light-shielding layer 120 may be located on a single straight line, and the edge of the first lower surface 1192 of the first light-shielding layer 119 may be located inside the straight line. In other words, the edge of the first lower surface 1192 of the first light-shielding layer 119 may not touch or overlap the straight line described above.

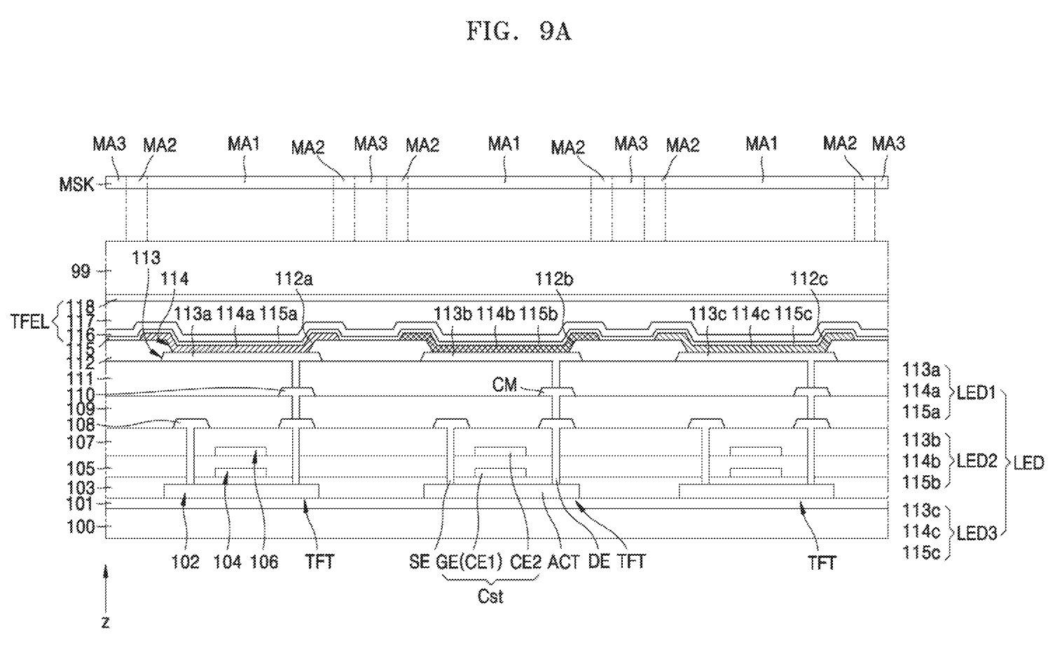

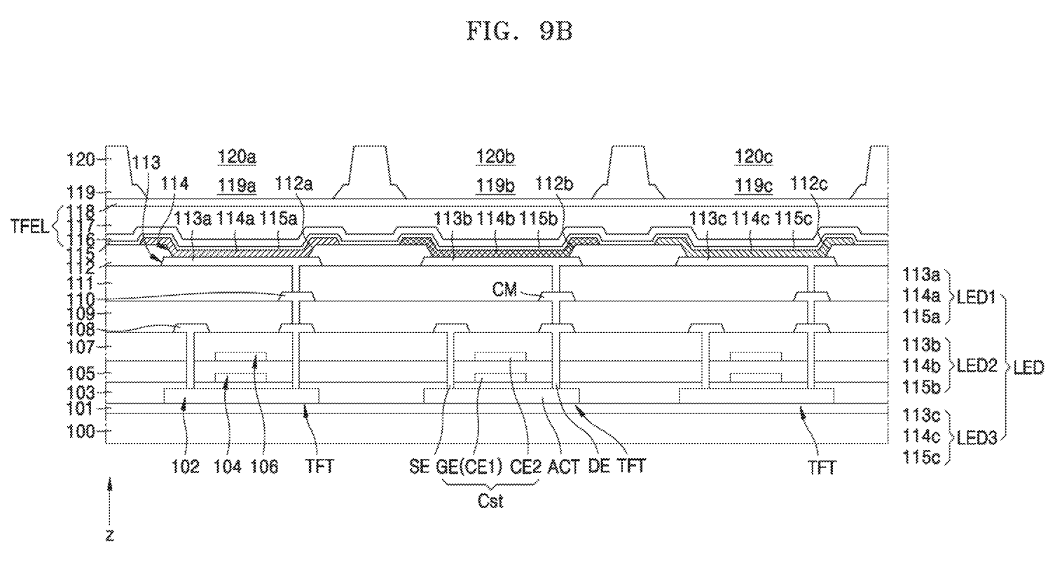

FIGS. 9A and 9B are cross-sectional views illustrating processes of a method of manufacturing a display panel, according to some embodiments. FIGS. 9A and 9B show a process of arranging the first light-shielding layer 119 and the second light-shielding layer 120 on the thin-film encapsulation layer TFEL.

Referring to FIG. 9A, a preliminary layer 99 may be arranged on the thin-film encapsulation layer TFEL. The preliminary layer 99 may entirely cover the thin-film encapsulation layer TFEL. According to some embodiments, the preliminary layer 99 may include a liquid-repellent material. A mask MSK may be arranged on the preliminary layer 99. According to some embodiments, the mask MSK may be a half tone mask. For example, the mask MSK may include a first mask area MA1, a second mask area MA2, and a third mask area MA3. The first mask area MA1 or the third mask area MA3 may be arranged between adjacent second mask areas MA2. Alternatively, the second mask area MA2 may be arranged between the first mask area MA1 and the third mask area MA3. According to some embodiments, the first mask area MA1 may be a transmissive area which completely transmits light, the second mask area MA2 may be a semi-transmissive area which partially transmits light, and the third mask area MA3 may be a blocking area which blocks light.

Referring to FIGS. 9A and 9B, the preliminary layer 99 may be exposed and etched to form the first light-shielding layer 119 and the second light-shielding layer 120. The first-1 to first-3 openings 119a, 119b, and 119c and the second-1 to second-3 openings 120a, 120b, and 120c may be formed in areas corresponding to the first mask area MA1 and the second mask area MA2. In the area corresponding to the first mask area MA1, the preliminary layer 99 may be completely removed, and an upper surface of the thin-film encapsulation layer TFEL (or the upper surface of the touch input layer) may be exposed. In the area corresponding to the second mask area MA2, the preliminary layer 99 may be partially removed to form tapered structures of the first light-shielding layer 119 and the second light-shielding layer 120. The area corresponding to the third mask area MA3 may not be removed because light is blocked in the area. According to some embodiments, the first light-shielding layer 119 and the second light-shielding layer 120 may be integrally formed as one body. According to some embodiments, the first light-shielding layer 119 and the second light-shielding layer 120 may include a same material. According to some embodiments, the first light-shielding layer 119 and the second light-shielding layer 120 may include a liquid-repellent material. In the present embodiment, a shape and/or dimension of the taper of the first light-shielding layer 119 and/or the second light-shielding layer 120 may be adjusted by adjusting a numerical value and/or profile of transmittance of the mask MSK, e.g., transmittance of the second mask area MA2.

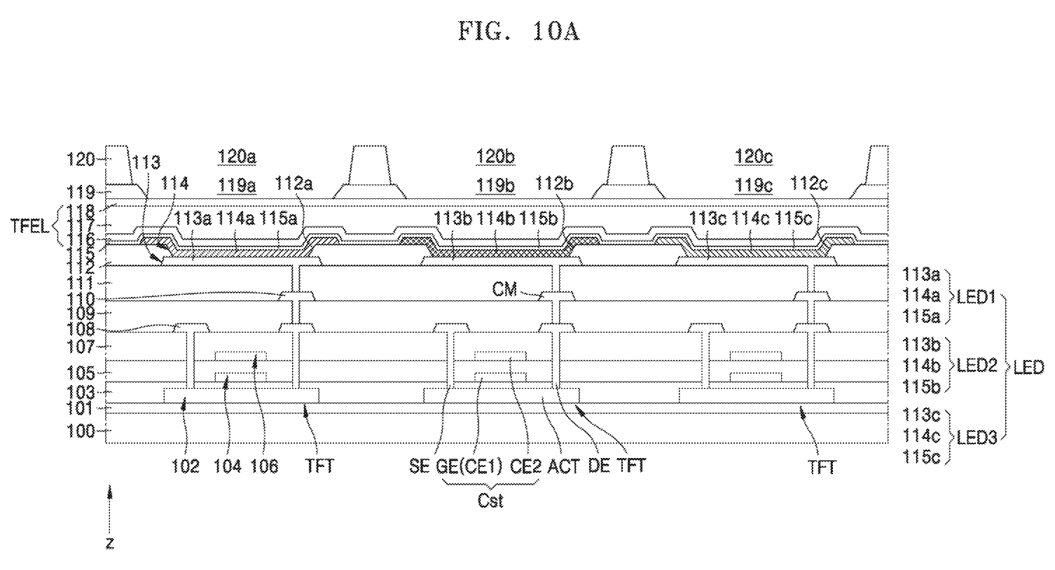

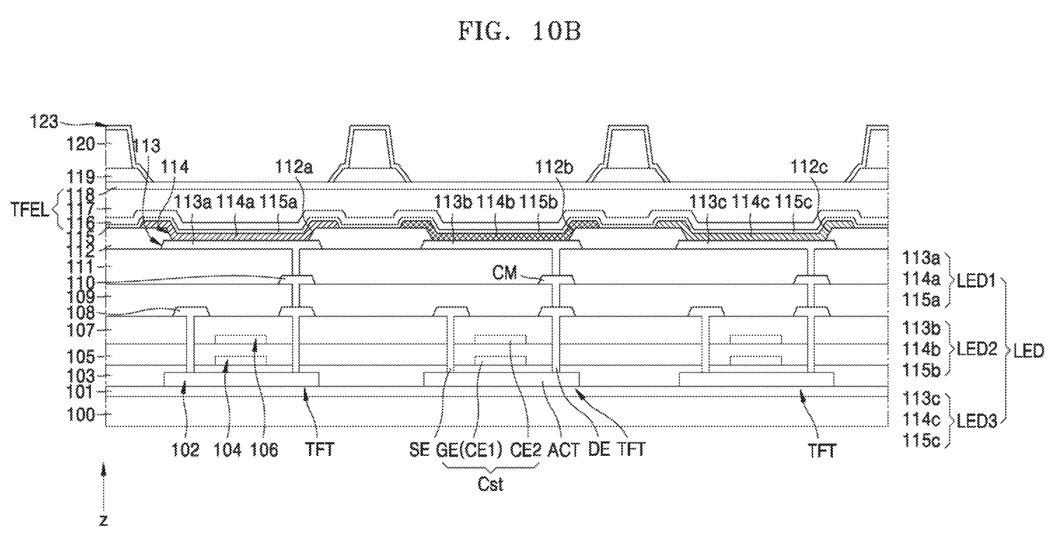

FIGS. 10A and 10B are cross-sectional views illustrating processes of a method of manufacturing a display panel, according to some embodiments. FIGS. 10A and 10B show a process of arranging the first light-shielding layer 119 and the second light-shielding layer 120 on the thin-film encapsulation layer TFEL.

Referring to FIG. 10A, the first light-shielding layer 119 and the second light-shielding layer 120 may be arranged on the thin-film encapsulation layer TFEL. Shapes and/or dimensions of the first light-shielding layer 119 and the second light-shielding layer 120 are the same as those described above with reference to FIGS. 7 and 8. In the present embodiment, the first light-shielding layer 119 and the second light-shielding layer 120 may include a lyophilic material.

Referring to FIG. 10B, a coating layer 123 may be arranged on the first light-shielding layer 119 and the second light-shielding layer 120. According to some embodiments, the coating layer 123 may include a liquid-repellent material. According to some embodiments, the coating layer 123 may include fluorine (F). According to some embodiments, a process of arranging the coating layer 123 may include a plasma treatment process. According to some embodiments, the process of arranging the coating layer 123 may include a process of coating the first light-shielding layer 119 and the second light-shielding layer 120 with F.

According to the one or more embodiments as described above, a display panel having a double light-shielding layer structure including a first light-shielding layer and a second light-shielding layer, and an electronic device including the display panel are provided. Thus, the quality (e.g., viewing angle and/or light-emitting area) of the display panel and electronic device may be relatively improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display panel comprising:
a plurality of light-emitting diodes each including a pixel electrode, an intermediate layer, and an opposite electrode;
a first light-shielding layer on the plurality of light-emitting diodes and including a plurality of first openings respectively overlapping the plurality of light-emitting diodes; and
a second light-shielding layer on the first light-shielding layer and including a plurality of second openings respectively overlapping the plurality of first openings,
wherein a first width of the first light-shielding layer between two adjacent first openings of the plurality of first openings is greater than a second width of the second light-shielding layer between two adjacent second openings of the plurality of second openings, and
the second light-shielding layer includes a liquid-repellent material.

2. The display panel of claim 1, wherein the first light-shielding layer includes a liquid-repellent material.

3. The display panel of claim 1, wherein a thickness of the first light-shielding layer is 2 micrometers or less.

4. The display panel of claim 1, wherein a thickness of the second light-shielding layer is 5 micrometers or less.

5. The display panel of claim 1, wherein the first light-shielding layer includes a first upper surface, a first lower surface, and a first side surface extending between the first upper surface and the first lower surface,
the second light-shielding layer includes a second upper surface, a second lower surface, and a second side surface extending between the second upper surface and the second lower surface, and
the first upper surface and the second lower surface are in direct contact with each other.

6. The display panel of claim 5, wherein an angle between the first lower surface and the first side surface is 55° or less.

7. The display panel of claim 5, wherein an angle between the second lower surface and the second side surface is 90° or less.

8. The display panel of claim 5, wherein, in a direction parallel to the first lower surface, a distance between an edge of the first lower surface and an edge of the second upper surface is 4.5 micrometers or less.

9. The display panel of claim 5, further comprising a pixel-defining layer under the first light-shielding layer and covering an edge area of the pixel electrode,
wherein a straight line connecting an edge of the pixel-defining layer in contact with the pixel electrode and an edge of the first lower surface of the first light-shielding layer forms an angle of 55° to 65° with an upper surface of the pixel electrode.

10. The display panel of claim 9, wherein, in a direction parallel to the first lower surface, a distance between the edge of the pixel-defining layer in contact with the pixel electrode and the edge of the first lower surface of the first light-shielding layer is 4 micrometers to 6 micrometers.

11. A display panel comprising:
a plurality of light-emitting diodes each including a pixel electrode, an intermediate layer, and an opposite electrode;
a pixel-defining layer including an opening overlapping the pixel electrodes of the plurality of light-emitting diodes and covering an edge area of the pixel electrode;
a first light-shielding layer on the pixel-defining layer and overlapping the pixel-defining layer, the first light-shielding layer including a first upper surface, a first lower surface, and a first side surface connecting the first upper surface and the first lower surface to each other; and
a second light-shielding layer on the first light-shielding layer and overlapping the first light-shielding layer, the second light-shielding layer including a second upper surface, a second lower surface, and a second side surface connecting the second upper surface and the second lower surface to each other,
wherein an angle formed by a straight line connecting an edge of the pixel-defining layer in contact with an upper surface of the pixel electrode and an edge of the first lower surface with the upper surface of the pixel electrode or
an angle formed by a straight line connecting the edge of the pixel-defining layer in contact with the upper surface of the pixel electrode and an edge of the second upper surface is 55° to 65°.

12. The display panel of claim 11, wherein the second light-shielding layer includes a liquid-repellent material.

13. The display panel of claim 11, wherein a width of the first upper surface of the first light-shielding layer is greater than a width of the second lower surface of the second light-shielding layer.

14. The display panel of claim 11, wherein a distance between the first upper surface and the first lower surface is 2 micrometers or less.

15. The display panel of claim 11, wherein a distance between the second upper surface and the second lower surface is 5 micrometers or less.

16. The display panel of claim 11, wherein an angle between the first lower surface and the first side surface is 55° or less.

17. The display panel of claim 11, wherein an angle between the second lower surface and the second side surface is 90° or less.

18. The display panel of claim 11, wherein, in a direction parallel to the first lower surface, a distance between the edge of the first lower surface and the edge of the second upper surface is 4.5 micrometers or less.

19. The display panel of claim 11, wherein, in a direction parallel to the first lower surface, a distance between the edge of the pixel-defining layer in contact with the upper surface of the pixel electrode and the edge of the first lower surface of the first light-blocking layer is in a range of 4 micrometers to 6 micrometers.

20. An electronic device comprising a display panel, wherein the display panel comprises:
a plurality of light-emitting diodes each including a pixel electrode, an intermediate layer, and an opposite electrode;
a first light-shielding layer on the plurality of light-emitting diodes and including a plurality of first openings respectively overlapping the plurality of light-emitting diodes; and
a second light-shielding layer on the first light-shielding layer and including a plurality of second openings respectively overlapping the plurality of first openings,
wherein a first width of the first light-shielding layer between two adjacent first openings from among the plurality of first openings is greater than a second width of the second light-shielding layer between two adjacent second openings from among the plurality of second openings, and
the second light-shielding layer includes a liquid-repellent material.
